(19) United States
(12) Patent Application Publication
(10) Pub. No.: US 2025/0323111 A1
(43) Pub. Date: Oct. 16, 2025

(54) Scalable Thermal Diode Implementation in Monolithic and Multi-Die FPGAs

(71) Applicants: Yee Kin Lum, Paya Terubong (MY); Kah Hooi Lim, Bayan Lepas (MY); Hon Khet Chuah, Bayan Lepas (MY); Teik Wah Lim, Bayan Lepas (MY); Jia Shern Fong, Kuala Terengganu (MY); Wan Muhammad Haikal Sobri, Bandar Baru Bangi (MY)

(72) Inventors: Yee Kin Lum, Paya Terubong (MY); Kah Hooi Lim, Bayan Lepas (MY); Hon Khet Chuah, Bayan Lepas (MY); Teik Wah Lim, Bayan Lepas (MY); Jia Shern Fong, Kuala Terengganu (MY); Wan Muhammad Haikal Sobri, Bandar Baru Bangi (MY)

(21) Appl. No.: 19/251,058

(22) Filed: Jun. 26, 2025

(51) Int. Cl. H01L 23/34; G01K 7/01; H01L 21/66; H01L 23/00; H01L 23/48; H01L 23/538; H01L 25/065; H05K 1/18

(52) U.S. Cl. CPC H01L 23/34; G01K 7/01; H01L 22/20; H01L 23/481; H01L 24/14; H01L 24/16; H01L 25/0655; G01K 2217/00; H01L 23/5385; H01L 2224/1403; H01L 2224/16225; H05K 1/181

(57) ABSTRACT

Systems or methods of the present disclosure may provide for any suitable number of thermal diodes selectively coupled to a single pair of package balls via a plurality of switches. That is, multiple thermal diodes may all be coupled to the single pair of package balls, which reduces a number of package balls coupled to the thermal diodes and increases a number of package balls available to other components. Additionally or alternatively, reducing the number of package balls coupled to the thermal diodes may reduce a size of the systems of the present disclosure.

### BACKGROUND

The present disclosure relates generally to integrated circuits, such as processors and/or field-programmable gate arrays (FPGAs). More particularly, the present disclosure relates to implementing thermal diodes in FPGAs.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuit devices, including programmable logic devices, may implement a circuit design. The integrated circuit device may include billions of transistors that generate heat during operation based on the implemented circuit design. For example, the integrated circuit device may include one or more hot spot regions based on the circuit design. As such, the integrated circuit device may include multiple temperature sensing elements at different locations of the integrated circuit device to measure temperatures at various hot spot regions.

During manufacturing of the integrated circuit device, for example, the temperature sensing elements may be calibrated. The integrated circuit device may include thermal diodes that measure a temperature of a region of the integrated circuit device. The temperature measured by the thermal diode may be compared to the temperature measured by the temperature sensing element, and based on a difference between the temperature measurements, the temperature sensing element may be calibrated.

In certain instances, a distance between the thermal diode and the temperature sensing element may reduce an accuracy of the temperature measured by the thermal diode for calibrating the thermal sensing element. To improve accuracy of the calibration, the thermal diode may be positioned proximate to the temperature sensing element. However, the thermal diode may be bonded to the integrated circuit device, thereby reducing a number of connections available to other components within the integrated circuit device.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit system, in accordance with an embodiment of the present disclosure;

FIG. 2 is a block diagram of the integrated circuit system of FIG. 1, in accordance with an embodiment of the present disclosure;

FIG. 3 is a schematic diagram of the integrated circuit system of FIG. 1 including thermal diodes in a 2.5-dimensional form, in accordance with an embodiment of the present disclosure;

FIG. 4 is a schematic diagram of the integrated circuit system of FIG. 1 including thermal diodes in a 3-dimensional form, in accordance with an embodiment of the present disclosure;

FIG. 5 is a perspective diagram of the integrated circuit system of FIG. 1, in accordance with an embodiment of the present disclosure;

FIG. 6 is a flowchart of an example method for operating the integrated circuit of FIG. 1, in accordance with an embodiment of the present disclosure; and

FIG. 7 is a block diagram of a data processing system including the integrated circuit system of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present systems and techniques relate to embodiments for a cost-effective and scalable thermal diode implement in integrated circuits. For example, the disclosed embodiments include a thermal diode design that selectively couples to a thermal diode of multiple thermal diodes within an integrated circuit via switches for temperature sensing. As such, multiple thermal diodes may be implemented within an integrated circuit and couple to a single pair of package balls (e.g., a pair of ball grid array (BGA) balls) of an integrated circuit system, thereby reducing a number of package balls coupled to the thermal diodes and increasing a number of package balls available to couple to other components of the integrated circuit.

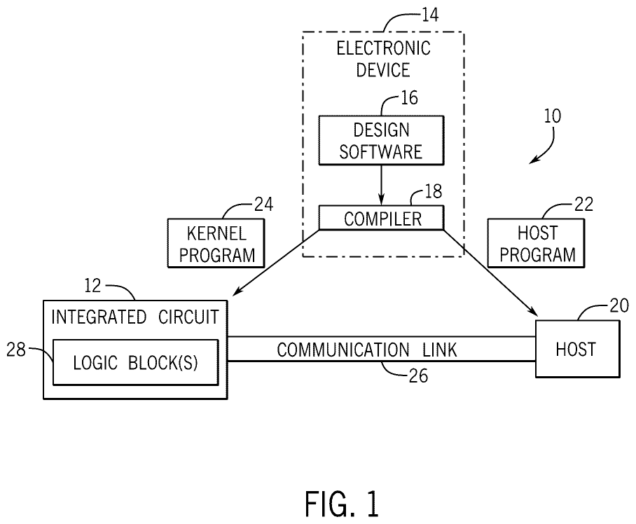

With the foregoing in mind, FIG. 1 illustrates a block diagram of a system 10 that may be used to receive temperature measurements from multiple thermal diodes as described in this disclosure within an integrated circuit system 12 (e.g., a single monolithic integrated circuit or a multi-die system of integrated circuits). The integrated circuit system 12 may include a single integrated circuit, multiple integrated circuits in a package, or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

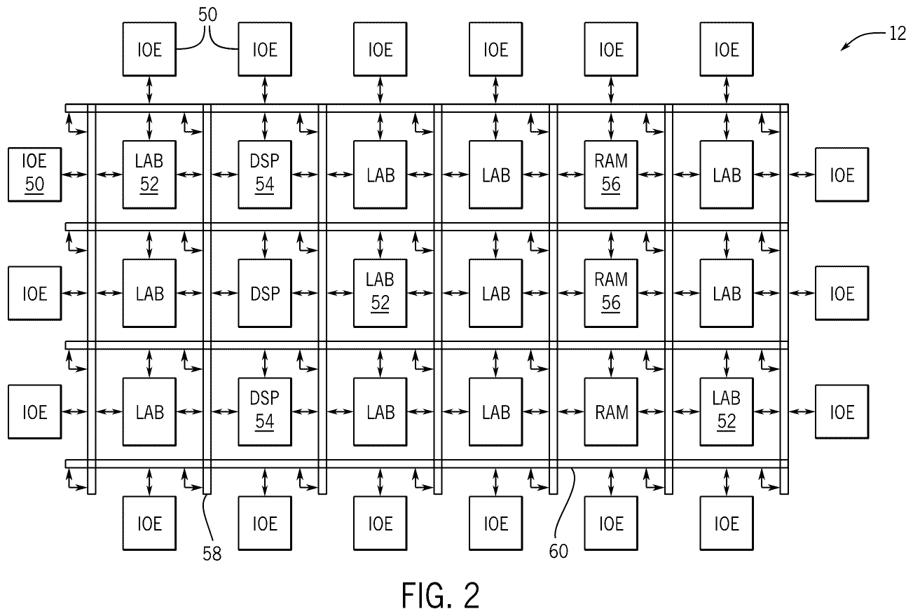

The integrated circuit system 12 may include a field-programmable gate array (FPGA). In a configuration mode of the integrated circuit system 12, a designer may use an electronic device 14 (e.g., a computer) to implement high-level designs (e.g., a system user design) using design software 16, such as a version of INTEL® QUARTUS® by INTEL CORPORATION. The electronic device 14 may use the design software 16 and a compiler 18 to convert the high-level program into a lower-level description (e.g., a configuration program, a bitstream). The compiler 18 may provide machine-readable instructions representative of the high-level program to a host 20 and the integrated circuit system 12. The host 20 may receive a host program 22 that may control or be implemented by a kernel program 24. To implement the host program 22, the host 20 may communicate instructions from the host program 22 to the integrated circuit system 12 via a communication link 26 that may include, for example, direct memory access (DMA) communications or peripheral component interconnect express (PCIe) communications. As will be described in greater detail below in FIG. 2, in some embodiments, the kernel program 24 and the host 20 may enable configuration of a logic block 28 on the integrated circuit system 12. The logic block 28 may include circuitry and/or other logic elements and may be configurable to implement a variety of functions in combination with digital signal processing (DSP) blocks.

The designer may use the design software 16 to generate and/or to specify a low-level program, such as the low-level hardware description languages described above. Further, in some embodiments, the system 10 may be implemented without the host program 22. Thus, embodiments described herein are intended to be illustrative and not limiting.

An illustrative embodiment of the integrated circuit system 12 such as a programmable logic device (PLD) that may be configured to implement a circuit design is shown in FIG. 2. As illustrated in FIG. 2, the integrated circuit system 12 (e.g., an FPGA) may include a 2-dimensional array of functional blocks, including programmable logic blocks 52 (also referred to as logic array blocks (LABs) or configurable logic blocks (CLBs)) and other functional blocks, such as embedded digital signal processing (DSP) blocks 54 and embedded random-access memory (RAM) blocks 56, for example. Functional blocks such as LABs 52 may include smaller programmable regions (e.g., logic elements, configurable logic blocks, or adaptive logic modules) that receive input signals and perform custom functions on the input signals to produce output signals. LABs 52 may also be grouped into larger programmable regions sometimes referred to as logic sectors that are individually managed and configured by corresponding logic sector managers. The grouping of the programmable logic resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy.

Programmable logic in the integrated circuit system 12 may contain programmable memory elements. Memory elements may be loaded with configuration data (also called programming data or configuration bitstream) using input-output elements (IOEs) 50. Once loaded, the memory elements each provide a corresponding static control signal that controls the operation of an associated functional block (e.g., LABs 52, DSP 54, RAM 56, or IOEs 50).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), lookup tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements.

In addition, the programmable logic device may have IOEs 50 for driving signals off the integrated circuit system 12 and for receiving signals from other devices. The IOEs 50 may include parallel input-output circuitry, serial data transceiver circuitry, differential receiver and transmitter circuitry, or other circuitry used to connect one integrated circuit to another integrated circuit. The integrated circuit system 12 may also include programmable interconnect circuitry in the form of vertical routing channels 58 (e.g., interconnects formed along a vertical axis of the integrated circuit system 12) and horizontal routing channels 60 (e.g., interconnects formed along a horizontal axis of the integrated circuit system 12), each routing channel including at least one track to route at least one wire. If desired, the interconnect circuitry may include pipeline elements, and the contents stored in these pipeline elements may be accessed during operation. For example, a programming circuit may provide read and write access to a pipeline element.

The integrated circuit system 12 may be configured to implement a custom circuit design. For example, the configuration RAM may be programmed such that LABs 52, DSP 54, and RAM 56, programmable interconnect circuitry (e.g., vertical routing channels 58 and horizontal routing channels 60), and the IOEs 50 form the circuit design implementation.

Note that other routing topologies, besides the topology of the interconnect circuitry depicted in FIG. 2, are intended to be included within the scope of the present invention. For example, the routing topology may include wires that travel diagonally or that travel horizontally and vertically along different parts of their extent as well as wires that are perpendicular to the device plane in the case of 3-dimensional integrated circuits, and the driver of a wire may be located at a different point than one end of a wire. The routing topology may include global wires that span substantially all of the integrated circuit system 12, fractional global wires such as wires that span part of the integrated circuit system 12, staggered wires of a particular length, smaller local wires, or any other suitable interconnection resource arrangement.

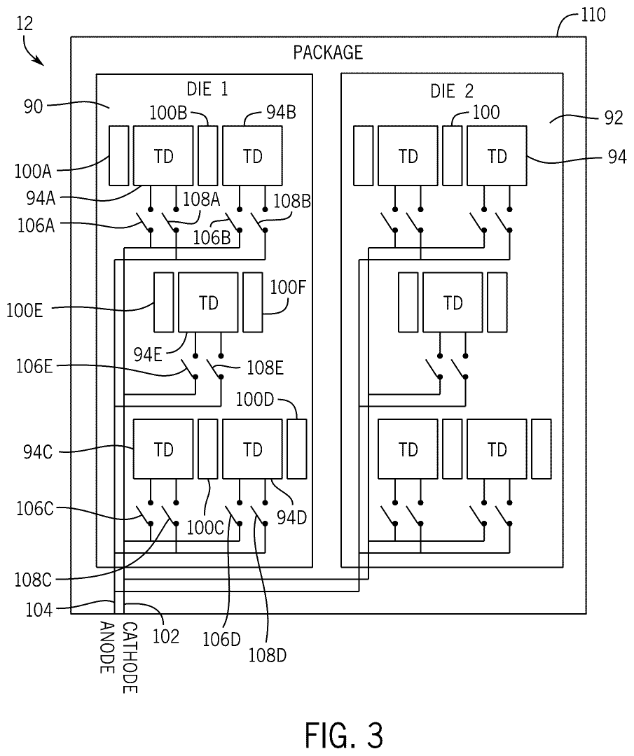

FIG. 3 is a schematic diagram of the integrated circuit system 12 including a first integrated circuit 90 and a second integrated circuit 92 in a 2.5-dimensional (2.5D) form, where the integrated circuits 90, 92 include thermal diodes 94 coupled to a current source via switches 96, 98. In the 2.5D form, the first integrated circuit 90 may be positioned adjacent to the second integrated circuit 92. Although the integrated circuit system 12 of FIG. 3 includes two integrated circuits 90, 92, it may be understood that the integrated circuit system 12 may include any suitable number of integrated circuits. For example, the integrated circuit system 12 may include one integrated circuit 90, 92 with multiple thermal diodes 94 coupled to a single pair of package balls. In another example, the integrated circuit system 12 may include more than two integrated circuits, where each integrated circuit includes multiple thermal diodes 94, and where all of the thermal diodes of the integrated circuits are coupled to a single pair of package balls.

The thermal diodes 94 may be positioned across an integrated circuit 90, 92. For example, the first integrated circuit 90 includes five thermal diodes 94 and the second integrated circuit 92 may include five thermal diodes 94. A first thermal diode 94A may be positioned in a first corner of the first integrated circuit 90, a second thermal diode 94B may be positioned in a second corner of the first integrated circuit 90, a third thermal diode 94C may be positioned in a third corner of the first integrated circuit 90, a fourth thermal diode 94D may be positioned in a fourth corner of the first integrated circuit 90, and a fifth thermal diode 94E may be positioned in a center of the first integrated circuit 90. Although the illustrated example includes five thermal diodes 94 within an integrated circuit 90, 92, it may be understood that there may be any suitable number of thermal diodes 94 positioned within each of the integrated circuit 90, 92, where all of the thermal diodes 94 may be coupled to a single pair of package balls. Additionally or alternatively, it may be understood that the thermal diodes 94 may be positioned in any suitable location of the integrated circuit 90, 92.

The integrated circuit 90, 92 may include multiple thermal sensing elements 100 positioned across the integrated circuit 90, 92. The thermal sensing elements 100 may monitor a temperature at a location of the integrated circuit 90, 92 during operation of the integrated circuit 90, 92. For example, the thermal sensing elements 100 may include a sensor to measure the temperature. The thermal diodes 94 may be positioned proximate to respective thermal sensing elements 100 to reduce a distance between the two components. In another example, the thermal sensing elements 100 may sense temperature through diode current sensing or resistance variation due to temperature changes. As illustrated, a first thermal sensing element 100A may be positioned proximate the first thermal diode 94A, a second thermal sensing element 100B may be positioned between the first thermal diode 94A and the second thermal diode 94B, a third thermal sensing element 100C may be positioned between the third thermal diode 94C and the fourth thermal diode 94D, a fourth thermal sensing element 100D may be positioned proximate the fourth thermal diode 94D, and a fifth thermal sensing element 100E and a sixth thermal sensing element 100F may be positioned proximate to the fifth thermal diode 94E.

The thermal diodes 94 may generate a measurement indicative of a temperature of the integrated circuit 90, 92. For example, the first thermal diode 94A may generate a measurement indicative of a temperature of the first corner of the first integrated circuit 90, the second thermal diode 94B may generate a measurement indicative of a temperature of the second corner of the first integrated circuit 90, and so on. The thermal diodes 94 may generate a voltage that corresponds to a temperature based on a property of electrical diodes to change voltage across it according to temperature. For example, a forward voltage drop across the thermal diode 94 may decrease with increasing temperature at a known rate. As such, a voltage outputted by the thermal diode 94 may correspond to a temperature reading, and the thermal diodes 94 may monitor temperature at different locations of the integrated circuits 90, 92.

The measurement from the thermal diode 94 may be used to calibrate thermal sensing elements 100. During manufacturing of the integrated circuit 90, 92, for example, the thermal sensing elements 100 may be calibrated based on a comparison between a measurement indicative of a temperature generated by the thermal diode 94 and a measurement indicative of a temperature generated by the thermal sensing elements 100. For example, the measurement generated by the thermal sensing elements 100 may include a temperature measurement, a voltage measurement, and the like. For example, the integrated circuit 90, 92 may be communicatively coupled to an external device (e.g., a controller) that receives the measurement generated by the thermal diode 94 and the measurement generated by the thermal sensing elements 100. For example, the external device may calibrate the first thermal sensing element 100A based on comparison a measurement indicative of temperature measured by the first thermal diode 94A and a temperature measurement generated by the first thermal sensing element 100A. The external device may determine an offset value based on the comparison. The offset value may be applied to subsequent temperature measurements generated by the first thermal sensing element 100A, such as during operation of the integrated circuits 90, 92. In another example, the external device may calibrate the second thermal sensing element 100B based on a measurement indicative of a temperature generated by the first thermal diode 94A and/or the second thermal diode 94B and a temperature generated by the second thermal sensing element 100B. As such, the calibration may be performed using a measurement indicative of a temperature generated from a thermal diode 94 positioned proximate to the thermal sensing element 100. Decreasing a distance between a thermal diode 94 and a thermal sensing element 100 may improve accuracy of the calibration and/or reduce isothermality effects.

All of the thermal diodes 94 within the integrated circuit system 12 may be bonded to a single pair of package balls. The single pair of package balls may include a first package ball 102 that may include a cathode to provide a current flow to the thermal diode 94 and the second package ball 104 that may include an anode to accept a current flow from the thermal diode 94. The first package ball 102 and the second package ball 104 may be collectively referred to herein as the “single pair of package balls.” The thermal diodes 94 may be coupled to the package balls via metal traces that form a pathway between the package balls and each of the thermal diode 94.

The integrated circuit system 12 may include a first set of switches 106 and a second set of switches 108 may selectively couple a thermal diode 94 to the single pair of package balls. For example, the first set of switches 106 may couple the thermal diodes 94 to the first package ball 102 of the single pair of package balls and the second set of switches 108 may couple the thermal diodes 94 to the second package ball 104 of the single pair of package balls. For example, a first switch 106A of the first set of switches 106 and a second switch 108B of the second set of switches 108 may be closed, current may be provided to the first thermal diode 94A for operation. When the first switch 106A and the second switch 108A may be open, current may not be provided to the first thermal diode 94A. For example, to calibrate and/or test the first thermal sensing elements 100A and/or the second thermal sensing elements 100B, current may be provided to the first thermal diode 94A. During operation, the first thermal diode 94A may generate a measurement indicative of a temperature, which may be compared to temperature measurements generated by the first thermal sensing elements 100A and/or the second thermal sensing elements 100B for calibration of the two thermal sensing elements 100A, 100B. After calibrating the first thermal sensing element 100A and/or the second thermal sensing element 100B, the first switch 106A and the second switch 108A may open to stop current flow to the first thermal diode 94A. In certain instances, another pair of switches 106, 108 may close to provide current to another thermal diode 94. As such, the switches 106, 108 may couple and uncouple the thermal diodes 94 to provide current to the thermal diodes 94. In the illustrated example, multiple thermal diodes 94 may be positioned within the first integrated circuit 90 and the second integrated circuit 92, and all of the thermal diodes 94 may couple to two package balls, thereby reducing a number of package balls bounded to the thermal diodes and increasing a number of package balls available to other components within the integrated circuit system 12.

The first integrated circuit 90 and the second integrated circuit 92 may be mounted onto a package substrate 110. At least a portion of the pathway between the thermal diode 94 and the single pair of package balls may include at least a portion of the package substrate 110. In certain instances, the integrated circuits 90, 92 may couple to the package substrate 110 via an interposer and/or one or more bumps (e.g., microbumps, control collapse bumps, package build ups). As such, at least a portion of the pathway include at least a portion of the interposer and one or more bumps.

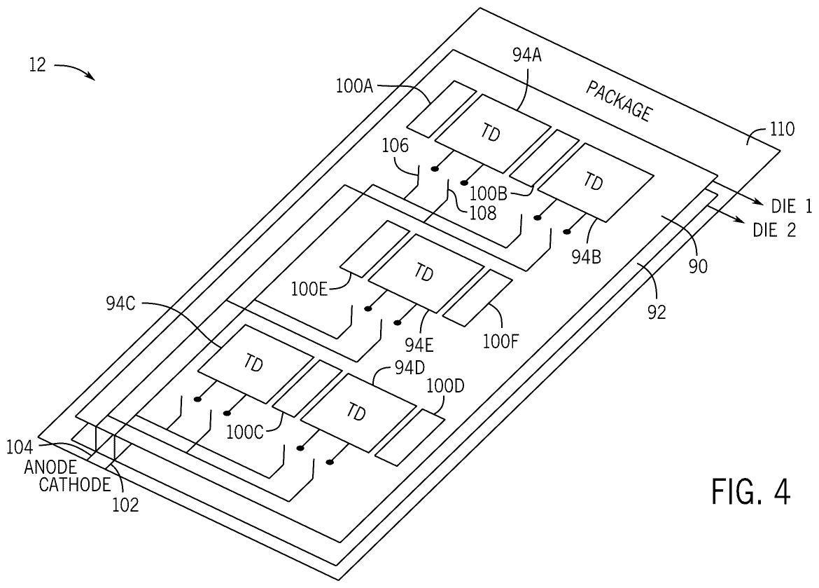

FIG. 4 is a schematic diagram of the integrated circuit system 12 including the first integrated circuit 90 and the second integrated circuit 92 in a 3-dimensional (3D) form, where the integrated circuits 90, 92 include thermal diodes 94 receive current via the first set of switches 106 and the second set of switches 108. In the 3D form, the first integrated circuit 90 may be stacked on top of the second integrated circuit 92.

In the illustrated example, only the first package ball 102 and the second package ball 104 are shared among the ten thermal diodes in the first integrated circuit 90 and the second integrated circuit 92. During calibration of the thermal sensing elements 100, only one thermal diode 94 may be coupled to the single pair of package balls at a time. For example, a first switch 106A of the first set of switches 106 and a second switch 108A of the second set of switches 108A may close to provide current to the first thermal diode 94A via the single pair of package balls. The remaining switches of the first set of switches 106 and the second set of switches 108 may remain open to uncouple the remaining thermal diodes 94 from the single pair of package balls. As such, current may be provided to the first thermal diode 94A for operation, and the current may not be provided to the remaining thermal diodes 94. As such, only one thermal diode 94 may coupled to the single pair of package balls at one time, which may reduce or eliminate corruption to the anode and/or cathode signal. The first thermal diode 94A may generate a measurement indicative of a temperature at the first corner of the first integrated circuit 90. After generation of the measurement, the first switch 106A and the second switch 108B may open to stop providing current to the first thermal diode 94A. In certain instances, a second switch 106B of the first set of switches 106 and a second switch 108B of the second set of switches 108 may close to couple the second thermal diode 94B to the single pair of package balls. As such, current may be provided to the second thermal diode 94B, and the second thermal diode 94B may generate a measurement indicative of a temperature of the second corner of the first integrated circuit 90. The process may continue until a measurement is generated by each thermal diode 94 within the integrated circuit system 12 and/or until a lapse of a pre-determined time period. For example, the process (e.g., a calibration process) may include causing each thermal diode 94 of the first integrated circuit 90 to generate a measurement then cause each thermal diode 94 of the second integrated circuit 92 to generate a measurement. The process may be performed using firmware control, user input via a controller, instructions stored within the controller, and so on. In another example, the process may include selecting a thermal diode 94 of the first integrated circuit 90 or the second integrated circuit 92 to generate the measurement based on user input (e.g., user selection). The measurements may be stored in a memory of the controller for subsequent use or used for calibrating the thermal sensing elements 100 in real-time or near real-time.

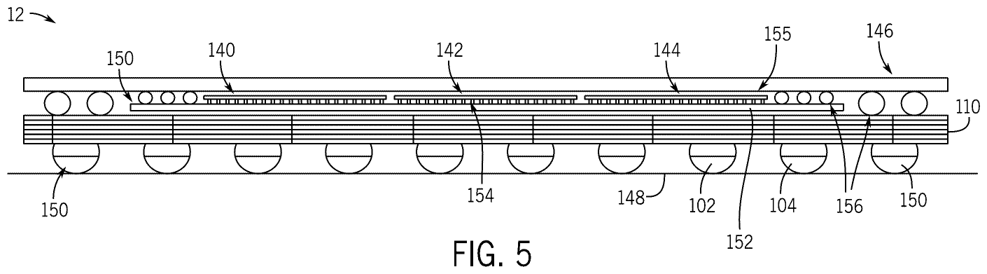

FIG. 5 is a perspective diagram of the integrated circuit system 12 with a first integrated circuit 140, a second integrated circuit 142, a third integrated circuit 144, and a fourth integrated circuit 146 (collectively referred to herein as “integrated circuits 140, 142, 144, and 146) in 2.5D and 3D forms. The integrated circuits 140, 142, 144, and 146 may each include thermal diodes 94 and thermal sensing elements 100 positioned across the integrated circuits 140, 142, 144, and 146. As discussed herein, all of the thermal diodes 94 within the integrated circuit system 12 may be selectively coupled to a single pair of package balls via the first set of switches 106 and the second set of switches 108 to receive current.

As illustrated, the integrated circuit system 12 may include the package substrate 110 mounted on a printed circuit board (PCB) 148 via ball grid array (BGA) balls 150. The BGA balls 150 may facilitate signal transfer between components of the integrated circuit system 12 and off-package components, provide current to the integrated circuit system 12, provide grounding between the integrated circuit system 12 and the PCB 148, and so on. As referred to herein, the single pair of package balls may include any two BGA balls 150. The single pair of package balls may provide current to the thermal diodes 94.

An interposer 152 may be mounted onto the package substrate 110. The interposer 152 may include an active interposer, a passive interposer, a bridge (e.g., an embedded multi-die interconnect bridge (EMIB)), or any combination thereof. The interposer 152 may facilitate signal transfer and power delivery between the first integrated circuit 140, the second integrated circuit 142, and the third integrated circuit 144 mounted onto the interposer 152. The interposer 152 may also facilitate signal transfer between the first integrated circuit 140, the second integrated circuit 142, and the third integrated circuit 144 and one or more additional components coupled to the interposer 152.

The first integrated circuit 140, the second integrated circuit 142, and the third integrated circuit 144 may respectively couple to the interposer 152 via one or more bumps 154. For example, the bumps 154 may include copper pillar micro-bumps with tin and silver solder caps (referred to herein as “C2 bumps”) 154. However, it may be understood that any bonding techniques that are suitable for coupling the integrated circuits 140, 142, 144 to the interposer 152 may be used. For example, the integrated circuits 140, 142, 144 may be coupled to the interposer 152 via high bandwidth interfaces (e.g., 2.5D interfaces, interconnect bridges, microbump interfaces) and/or any other suitable multi-channel interconnect.

The integrated circuit system 12 may include the fourth integrated circuit 146 stacked on top of the first integrated circuit 140, the second integrated circuit 142, and the third integrated circuit 144. The fourth integrated circuit 146 may be coupled to the first integrated circuit 140, the second integrated circuit 142, and the third integrated circuit 144 via through silicon vias (TSVs) 155. The TSVs 155 provide electric interconnects through the die (e.g., the first integrated circuit 140, the second integrated circuit 142, and the third integrated circuit 144) or wafer. In 2.5D forms and/or 3D forms, the distance between integrated circuits 140, 142,144, 146 may decrease, which may decrease power consumption and latency while increasing a number of connections. A decrease in interconnect distance may result in lower latency within the integrated circuit system 12 as a distance for signal transfer may decrease, a decrease in noise (e.g., reflection noise, crosstalk noise, simultaneous switching noise, electromagnetic interference), and/or a reduction in parasitic capacitance. Lower latency may improve bandwidth of the integrated circuit system 12. A reduction in parasitic capacitance may reduce total power consumption of the integrated circuit system 12.

The fourth integrated circuit 146 may also be coupled to the interposer 152 and the package substrate 110 via controlled collapse chip connection (C4) bumps 154. The C4 bumps 156 may be made from any suitable metal material. Both the C2 bumps 154 and the C4 bumps 156 may facilitate signal transfer between components of the integrated circuit system 12. The C2 bumps 154 may perform more efficiently thermally and electrically in comparison to the C4 bumps 156. The BGA balls 150 aligned with the C2 bumps 152 may include a smaller pitch size in comparison to the BGA balls 150 aligned with the C4 bumps 156.

As package ball size decreases, a size of the integrated circuit system 12 may decrease and/or a size of the integrated circuits 140, 142, 144, 146 may also decrease. As such, the integrated circuit system 12 may be produced in a cost-effective manner. Moreover, a size of the integrated circuit system 12 may be reduced by reducing a number of package balls coupled to the thermal diodes 94, which may increase a number of package balls available to other components of the integrated circuit system 12 and/or reduce the number of package balls used within the integrated circuit system 12. Additionally or alternatively, a smaller integrated circuit system 12 may consume less power and dissipate less heat in comparison to a larger integrated circuit system 12.

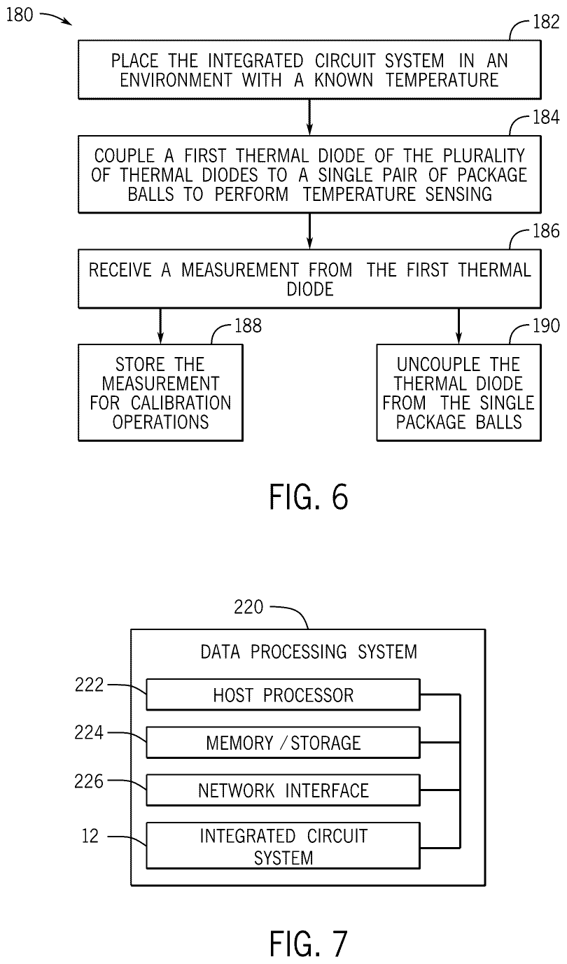

FIG. 6 is a flowchart of a method 180 for operating the integrated circuit system 12. For example, the thermal diodes of the integrated circuit (e.g., the integrated circuits 90, 92 of FIGS. 3 and 4, integrated circuits 140, 142, 144, 146 of FIG. 5) may be used to calibrate thermal sensing elements of the integrated circuit during manufacturing. As such, accuracy of the measurements generated by the thermal sensing elements may improve. In another example, the thermal diodes may be used to calibrate thermal sensing elements of the integrated circuit after manufacturing, such as by an owner (e.g. user, designer, customer) of the integrated circuit.

At block 182, the integrated circuit system may be placed in an environment with a known temperature. The temperature of the environment may be a known temperature and/or a uniform temperature. Additionally or alternatively, the integrated circuit system may be operated (e.g., provided a voltage level, provided a power) to reach a known temperature.

At block 184, a first thermal diode of a plurality of thermal diodes may be coupled to a single pair of package balls to perform temperature sensing. For example, a pair of switches may close to couple the first thermal diode to the package balls. The single pair of package balls may provide current to the first thermal diode for operation. The first thermal diode may generate a measurement indicative of a temperature at a location of the integrated circuit.

At block 186, a measurement from the first thermal diode may be received. The first thermal diode may provide the measurement to an external device coupled to the integrated circuit. The external device may include a controller.

At block 188, the measurement for calibration operations may be stored. The measurements may be stored in a metal fuse integrated within the integrated circuit system. The external device may store the measurement in a memory of the external device. In other examples, the external device may store the measurement in a database, a cloud server, and the like. The external device may also receive a measurement from first thermal sensing elements of a plurality of thermal sensing elements for the calibration operations. The first thermal sensing elements may be positioned proximate to the first thermal diode. The distance between the first thermal sensing elements and the first thermal diode may be close enough such that the first thermal diode and the first thermal sensing elements may include the same characteristics.

The external device may compare the measurement from the first thermal diode and the first thermal sensing elements to determine an offset value for the first thermal sensing elements. For example, the comparison may be based on a mathematics curve fitting concept. The offset value may be used for subsequent measurements generated by the first thermal sensing elements during operation of the integrated circuit.

At block 190, the first thermal diode may be uncoupled from the single pair of package balls. For example, the pair of switches may open to uncouple the first thermal diode from the single pair of package balls. As such, the first thermal diode may not receive current and may not generate a measurement. In certain instances, a second pair of switches may close to couple a second thermal diode of the plurality of thermal diodes to the single pair of package balls to perform calibration operations with second thermal sensing elements of the plurality of thermal sensing elements. In other instances, the calibration operation may be completed and all of the thermal diodes of the integrated circuit may be uncoupled from the single pair of package balls.

The method 180 includes various steps represented by blocks. Although the flowchart illustrates the steps in a certain sequence, it should be understood that the steps may be performed in any suitable order and certain steps may be carried out simultaneously, where appropriate. Further, certain steps or portions of the method 180 may be performed by separate systems or devices.

The processes discussed above may be carried out on the integrated circuit system 12, which may be a component included in a data processing system, such as a data processing system 220, shown in FIG. 8. The data processing system 220 may include the integrated circuit system 12, a host processor 222, memory and/or storage circuitry 224, and a network interface 226. The data processing system 220 may include more or fewer components (e.g., electronic display, user interface structures, application specific integrated circuits (ASICs)). The host processor 222 may include any of the foregoing processors that may manage a data processing request for the data processing system 220 (e.g., to perform elaboration and simulation, to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 224 may include random access memory (RAM), read-only memory (ROM), one or more hard drives, flash memory, or the like. The memory and/or storage circuitry 224 may hold data to be processed by the data processing system 220. In some cases, the memory and/or storage circuitry 224 may also store configuration programs (e.g., bitstreams, mapping function) for programming the integrated circuit system 12. The network interface 226 may allow the data processing system 220 to communicate with other electronic devices. The data processing system 220 may include several different packages or may be contained within a single package on a single package substrate. For example, components of the data processing system 220 may be located on several different packages at one location (e.g., a data center) or multiple locations. For instance, components of the data processing system 220 may be located in separate geographic locations or areas, such as cities, states, or countries.

The data processing system 220 may be part of a data center that processes a variety of different requests. For instance, the data processing system 220 may receive a data processing request via the network interface 226 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. For example, other integrated circuits, such as graphics cards, hard drives, or other components, may include multiple thermal diodes that all couple to a single pair of package balls via switches. A first pair of switches associated with a first thermal diode may close to provide current to the first thermal diode. Then, the first pair of switches may open to stop providing current to the first thermal diode and a second pair of switches associated with a second thermal diode may close to provide current to the second thermal diode, and so on. As such, the techniques and methods described herein may provide for smaller integrated circuit systems and/or integrated circuit systems with an improved calibration process for thermal sensing elements within the integrated circuit systems, and so on.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

EXAMPLE EMBODIMENT 1. An integrated circuit including plurality of thermal diodes to respectively generate a measurement indicative of a temperature; and a plurality of switches to selectively provide a current to each thermal diode of the plurality of thermal diodes, where all of the plurality of thermal diodes receives the current via a single pair of package balls.

EXAMPLE EMBODIMENT 2. The integrated circuit of example embodiment 1, wherein a first pair of switches of the plurality of switches is to close to selectively provide current to a first thermal diode of the plurality of thermal diodes.

EXAMPLE EMBODIMENT 3. The integrated circuit of example embodiment 2, where the first pair of switches is to open to stop providing current to the first thermal diode, and wherein a second pair of switches of the plurality of switches is to close to selectively provide the current to a second thermal diode of the plurality of thermal diodes

EXAMPLE EMBODIMENT 4. The integrated circuit of example embodiment 2, comprising a plurality of thermal sensing elements, wherein a first thermal sensing element of the plurality of thermal sensing elements is positioned proximate to the first thermal diode.

EXAMPLE EMBODIMENT 5. The integrated circuit of example embodiment 4, comprising a controller to receive a first measurement indicative of a temperature from the first thermal diode, receive a second measurement indicative of a temperature from the first thermal sensing element, and determine an offset value for the first thermal sensing element based on a comparison between the first measurement and the second measurement.

EXAMPLE EMBODIMENT 6. The integrated circuit of example embodiment 4, wherein the controller stores the offset value in a memory for subsequent measurements from the first thermal sensing element.

EXAMPLE EMBODIMENT 7. The integrated circuit of example embodiment 1, wherein a first package ball of the single pair of package balls comprises a cathode source and a second package ball of the single pair of package balls comprises an anode source.

EXAMPLE EMBODIMENT 8. A multi-die package including a plurality of ball grid array (BGA) balls, a package substrate coupled to the plurality of BGA balls, and a first integrated circuit mounted on the package substrate. The first integrated circuit may include a first set of thermal diodes, and a first plurality of switches to selectively couple each thermal diode of the first set of thermal diodes to a single pair of BGA balls of the plurality of BGA balls, and a second integrated circuit including a second set of thermal diodes; and a second plurality of switches to selectively couple each thermal diode of the second set of thermal diodes to the single pair of BGA balls.

EXAMPLE EMBODIMENT 9. The multi-die package of example embodiment 8, wherein the first integrated circuit and the second integrated circuit are positioned side by side.

EXAMPLE EMBODIMENT 10. The multi-die package of example embodiment 9, including a third integrated circuit coupled to the first integrated circuit, the second integrated circuit, and the package substrate, wherein the third integrated circuit comprises a third set of thermal diodes and a third plurality of switches to selectively couple each thermal diode of the third set of thermal diodes to the single pair of BGA balls.

EXAMPLE EMBODIMENT 11. The multi-die package of example embodiment 10, wherein the third integrated circuit is coupled to the package substrate via a first type of bumps, wherein the third integrated circuit is coupled to the first integrated circuit and the second integrated circuit via a second type of bumps, wherein the first type of bumps is different from the second type of bumps.

EXAMPLE EMBODIMENT 12. The multi-die package of example embodiment 8, wherein the second integrated circuit is mounted on top of the first integrated circuit.

EXAMPLE EMBODIMENT 13. The multi-die package of example embodiment 12, wherein the first integrated circuit and the second coupled via through silicon vias (TSVs).

EXAMPLE EMBODIMENT 14. The multi-die package of example embodiment 8, wherein all thermal diodes of the first set of thermal diodes and all thermal diodes of the second set of thermal diodes are coupled to the single pair of BGA balls.

EXAMPLE EMBODIMENT 15. An integrated circuit system may include a plurality of ball grid array (BGA) balls, a package substrate coupled to the plurality of BGA balls, and an integrated circuit mounted on the package substate. The integrated circuit may include a plurality of thermal sensing elements positioned across the integrated circuit, a plurality of thermal diodes positioned across the integrated circuit, wherein each of the plurality of thermal diodes are positioned proximate to a respective thermal sensing element of the plurality of thermal sensing elements, and a plurality of switches coupled to the plurality of thermal diodes, wherein the plurality of switches selectively couple the plurality of thermal diodes to a single pair of BGA balls.

EXAMPLE EMBODIMENT 16. The integrated circuit system of example embodiment 15, wherein a first pair of switches of the plurality of switches couples a first thermal diode of the plurality of thermal diodes to the single pair of BGA balls to provide current to the first thermal diode, wherein the first thermal diode generates a measurement indicative of a temperature measurement of the integrated circuit.

EXAMPLE EMBODIMENT 17. The integrated circuit system of example embodiment 16, wherein a first thermal sensing element of the plurality of thermal sensing elements generates a second measurement indicative of a temperature measurement of the integrated circuit.

EXAMPLE EMBODIMENT 18. The integrated circuit system of example embodiment 17, comprising a controller to receive the measurement from the first thermal diode and the second measurement from the first thermal sensing element and generate an offset value for the first thermal sensing element based on a comparison between the measurement and the second measurement.

EXAMPLE EMBODIMENT 19. The integrated circuit system of example embodiment 16, wherein the first pair of switches open to uncouple the first thermal diode from the single pair of BGA balls, and wherein a second pair of switches of the plurality of switches couples a second thermal diode of the plurality of thermal diodes to the single pair of BGA balls to provide current to the second thermal diode.

EXAMPLE EMBODIMENT 20. The integrated circuit system of example embodiment 16, wherein the remaining switches of the plurality of switches open or remain open to uncouple the remaining thermal diodes of the plurality of thermal diodes from the single pair of BGA balls.

What is claimed is:

1. An integrated circuit, comprising:
a plurality of thermal diodes to respectively generate a measurement indicative of a temperature; and
a plurality of switches to selectively provide a current to each thermal diode of the plurality of thermal diodes, wherein all of the plurality of thermal diodes receives the current via a single pair of package balls.

2. The integrated circuit of claim 1, wherein a first pair of switches of the plurality of switches is to close to selectively provide current to a first thermal diode of the plurality of thermal diodes.

3. The integrated circuit of claim 2, wherein the first pair of switches is to open to stop providing current to the first thermal diode, and wherein a second pair of switches of the plurality of switches is to close to selectively provide the current to a second thermal diode of the plurality of thermal diodes.

4. The integrated circuit of claim 2, comprising a plurality of thermal sensing elements, wherein a first thermal sensing element of the plurality of thermal sensing elements is positioned proximate to the first thermal diode.

5. The integrated circuit of claim 4, comprising a controller to:
receive a first measurement indicative of a temperature from the first thermal diode;
receive a second measurement indicative of a temperature from the first thermal sensing element; and
determine an offset value for the first thermal sensing element based on a comparison between the first measurement and the second measurement.

6. The integrated circuit of claim 4, wherein the controller stores the offset value in a memory for subsequent measurements from the first thermal sensing element.

7. The integrated circuit of claim 1, wherein a first package ball of the single pair of package balls comprises a cathode source and a second package ball of the single pair of package balls comprises an anode source.

8. A multi-die package, comprising:
a plurality of ball grid array (BGA) balls;
a package substrate coupled to the plurality of BGA balls; and
a first integrated circuit mounted on the package substrate, the first integrated circuit comprising:
a first set of thermal diodes; and
a first plurality of switches to selectively couple each thermal diode of the first set of thermal diodes to a single pair of BGA balls of the plurality of BGA balls; and
a second integrated circuit comprising:
a second set of thermal diodes; and
a second plurality of switches to selectively couple each thermal diode of the second set of thermal diodes to the single pair of BGA balls.

9. The multi-die package of claim 8, wherein the first integrated circuit and the second integrated circuit are positioned side by side.

10. The multi-die package of claim 9, comprising:
a third integrated circuit coupled to the first integrated circuit, the second integrated circuit, and the package substrate, wherein the third integrated circuit comprises a third set of thermal diodes and a third plurality of switches to selectively couple each thermal diode of the third set of thermal diodes to the single pair of BGA balls.

11. The multi-die package of claim 10, wherein the third integrated circuit is coupled to the package substrate via a first type of bumps, wherein the third integrated circuit is coupled to the first integrated circuit and the second integrated circuit via a second type of bumps, wherein the first type of bumps is different from the second type of bumps.

12. The multi-die package of claim 8, wherein the second integrated circuit is mounted on top of the first integrated circuit.

13. The multi-die package of claim 12, wherein the first integrated circuit and the second coupled via through silicon vias (TSVs).

14. The multi-die package of claim 8, wherein all thermal diodes of the first set of thermal diodes and all thermal diodes of the second set of thermal diodes are coupled to the single pair of BGA balls.

15. An integrated circuit system, comprising:
a plurality of ball grid array (BGA) balls;
a package substrate coupled to the plurality of BGA balls; and
an integrated circuit mounted on the package substate, wherein the integrated circuit comprises:
a plurality of thermal sensing elements positioned across the integrated circuit;
a plurality of thermal diodes positioned across the integrated circuit, wherein each of the plurality of thermal diodes are positioned proximate to a respective thermal sensing element of the plurality of thermal sensing elements; and
a plurality of switches coupled to the plurality of thermal diodes, wherein the plurality of switches selectively couple the plurality of thermal diodes to a single pair of BGA balls.

16. The integrated circuit system of claim 15, wherein a first pair of switches of the plurality of switches couples a first thermal diode of the plurality of thermal diodes to the single pair of BGA balls to provide current to the first thermal diode, wherein the first thermal diode generates a measurement indicative of a temperature measurement of the integrated circuit.

17. The integrated circuit system of claim 16, wherein a first thermal sensing element of the plurality of thermal sensing elements generates a second measurement indicative of a temperature measurement of the integrated circuit.

18. The integrated circuit system of claim 17, comprising a controller to:
receive the measurement from the first thermal diode and the second measurement from the first thermal sensing element; and
generate an offset value for the first thermal sensing element based on a comparison between the measurement and the second measurement.

19. The integrated circuit system of claim 16, wherein the first pair of switches open to uncouple the first thermal diode from the single pair of BGA balls, and wherein a second pair of switches of the plurality of switches couples a second thermal diode of the plurality of thermal diodes to the single pair of BGA balls to provide current to the second thermal diode.

20. The integrated circuit system of claim 16, wherein the remaining switches of the plurality of switches open or remain open to uncouple the remaining thermal diodes of the plurality of thermal diodes from the single pair of BGA balls.
